(19) United States
(12) Patent Application Publication
(10) Pub. No.: US 2024/0194624 A1
(43) Pub. Date: Jun. 13, 2024

(54) SEMICONDUCTOR CHIP AND SEMICONDUCTOR PACKAGE INCLUDING THE SAME

(71) Applicant: Samsung Electronics Co., Ltd., Suwon-si (KR)

(72) Inventors: Hyeonjeong Kim, Suwon-si (KR); Jongmin Lee, Suwon-si (KR); Jimin Choi, Suwon-si (KR)

(21) Appl. No.: 18/512,375

(22) Filed: Nov. 17, 2023

(30) Foreign Application Priority Data
Dec. 13, 2022 (KR) 10-2022-0174193

(51) Int. Cl. H01L 23/00; H01L 23/48; H01L 23/522; H01L 25/065

(52) U.S. Cl. CPC H01L 24/06; H01L 23/481; H01L 23/5226; H01L 25/0657; H01L 24/16; H01L 24/32; H01L 24/73; H01L 2224/06181; H01L 2224/16145; H01L 2224/32145; H01L 2224/73204

(57) ABSTRACT

A semiconductor chip includes a semiconductor substrate including an active surface and an inactive surface facing the active surface, a multi wiring layer arranged on the active surface of the semiconductor substrate, and including a wiring structure having at least two layers and including a conductive wiring and a dummy wiring, a lower protection layer arranged on a front surface of the multi wiring layer, and including a conductive medium pad connected to the conductive wiring, a plurality of through vias configured to penetrate the semiconductor substrate, and including a plurality of power through vias, a plurality of signal through vias, and a plurality of dummy through vias; and a plurality of back side pads arranged on the inactive surface of the semiconductor substrate, and connected to the plurality of through vias, wherein the plurality of dummy through vias are connected to the wiring structure.

### CROSS-REFERENCE TO RELATED APPLICATION

This application is based on and claims priority under 35 U.S.C. § 119 to Korean Patent Application No. 10-2022-0174193, filed on Dec. 13, 2022 in the Korean Intellectual Property Office, the disclosure of which is incorporated by reference herein in its entirety.

### BACKGROUND

Aspects of the inventive concept relate to a semiconductor chip and a semiconductor package including the semiconductor chip, and more particularly, to a semiconductor chip including a through via and a semiconductor package including the semiconductor chip.

Electronic devices have become more compact and lighter according to rapid development of the electronic industry and demands of users. Accordingly, high integration of semiconductor chips used in electronic devices is required, and design rules for components of semiconductor chips are further reduced. Typically, a semiconductor package mounts a semiconductor chip on a printed circuit board (PCB), and electrically connects the semiconductor chip to the PCB by using a connection member, such as a bonding wire and a bump. Recently, a semiconductor package implemented by stacking a plurality of semiconductor chips including through silicon via (TSV) on a PCB has been developed.

### SUMMARY

Aspects of the inventive concept provide a semiconductor chip with improved reliability.

Aspects of the inventive concept provide a semiconductor package with improved reliability.

According to an aspect of the inventive concept, there is provided a semiconductor chip. The semiconductor chip includes a semiconductor substrate including an active surface and an inactive surface facing the active surface, a multi wiring layer arranged on the active surface of the semiconductor substrate, and including a wiring structure having at least two layers and including a conductive wiring and a dummy wiring, a lower protection layer arranged on a front surface of the multi wiring layer, and including a conductive medium pad connected to the conductive wiring, an upper protection layer on the inactive surface of the semiconductor substrate, a plurality of through vias configured to penetrate the semiconductor substrate and the upper protection layer, and including a plurality of power through vias, a plurality of signal through vias, and a plurality of dummy through vias; and a plurality of back side pads arranged on a rear surface of the upper protection layer, and connected to the plurality of through vias, wherein the plurality of dummy through vias are connected to the wiring structure.

According to another aspect of the inventive concept, there is provided a semiconductor chip. The semiconductor chip includes a semiconductor substrate including an active surface and an inactive surface facing the active surface, a multi wiring layer arranged on the active surface of the semiconductor substrate, and including at least two layers of each of a conductive wiring and a dummy wiring, a lower protection layer including, therein, a conductive medium pad connected to the conductive wiring, and a dummy medium pad connected to the dummy wiring, the lower protection layer being arranged on a front surface of the multi wiring layer, an upper protection layer on the inactive surface of the semiconductor substrate, a plurality of through vias including a plurality of power through vias, a plurality of signal through vias, and a plurality of dummy through vias, and configured to penetrate the semiconductor substrate and the upper protection layer, and a plurality of back side pads including a plurality of back side power pads respectively connected to the plurality of power through vias, a plurality of back side signal pads respectively connected to the plurality of signal through vias, and a plurality of back side dummy pads respectively connected to the plurality of dummy through vias, the plurality of back side pads being arranged on a rear surface of the upper protection layer, wherein at least one of the plurality of back side power pads is connected to at least one of the plurality of back side dummy pads.

According to another aspect of the inventive concept, there is provided a semiconductor package. The semiconductor package includes a first semiconductor chip, and a second semiconductor chip on the first semiconductor chip, wherein the first semiconductor chip includes a first semiconductor substrate including a first active surface and a first inactive surface, which are opposite to each other, a first dummy wiring arranged in a first multi wiring layer on the first active surface of the first semiconductor substrate, a plurality of first back side dummy pads arranged on the first inactive surface of the first semiconductor substrate, and a plurality of first dummy through vias configured to penetrate the first semiconductor substrate and connected to the first dummy wiring and the plurality of first back side dummy pads, wherein the second semiconductor chip includes a second semiconductor substrate including a second active surface and a second inactive surface, which are opposite to each other, a second dummy wiring arranged in a second multi wiring layer on the second active surface of the second semiconductor substrate, and a plurality of second front side dummy pads connected to the second dummy wiring, and arranged on a front surface of the second multi wiring layer, and wherein the plurality of first back side dummy pads are respectively connected to the plurality of second front side dummy pads.

### BRIEF DESCRIPTION OF THE DRAWINGS

Embodiments will be more clearly understood from the following detailed description taken in conjunction with the accompanying drawings in which:

FIG. 1 is a perspective view of a semiconductor chip according to an embodiment;

FIG. 2 is a plan view of a semiconductor chip according to an embodiment, and is an enlarged view of region indicated as “EX1” in FIG. 1;

FIG. 3 is a cross-sectional view taken along line A1-A1′ in FIG. 2;

FIG. 4 is a cross-sectional view taken along line B1-B1′ in FIG. 2;

FIG. 5 is a cross-sectional view taken along line A1-A1′ of a semiconductor chip, according to other embodiments having a plan view of FIG. 2;

FIG. 6 is a cross-sectional view taken along line B1-B1′ of a semiconductor chip, according to other embodiments having a plan view of FIG. 2;

FIG. 7 is a cross-sectional view taken along line A1-A1′ of a semiconductor chip, according to some other embodiments having a plan view of FIG. 2;

FIG. 8 is a plan view of a semiconductor chip according to some other embodiments, and is an enlarged view of region indicated as “EX1” in FIG. 1;

FIG. 9 is a cross-sectional view taken along line A2-A2′ in FIG. 8;

FIG. 10 is a plan view of a semiconductor chip according to some other embodiments, and is an enlarged view of region indicated as “EX1” in FIG. 1;

FIG. 11 is a cross-sectional view taken along line A3-A3′ in FIG. 10;

FIG. 12 is a cross-sectional view of a semiconductor package according to an embodiment;

FIG. 13 is an enlarged view of region indicated by “EX2” in FIG. 12;

FIGS. 14 and 15 are respectively a perspective view and a cross-sectional view of a system package including a semiconductor package, according to embodiments; and

FIGS. 16A through 16E are cross-sectional views illustrating a method of manufacturing a semiconductor chip according to a process sequence, according to embodiments, and are cross-sectional views of region corresponding to a cross-sectional view taken along line A1-A1′ in FIG. 2.

### DETAILED DESCRIPTION OF THE EMBODIMENTS

Hereinafter, embodiments of the inventive concept are described in detail with reference to the accompanying drawings. Identical reference numerals are used for the same components in the drawings, and a duplicate description thereof will be omitted.

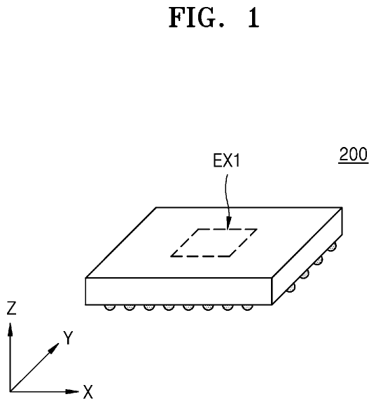

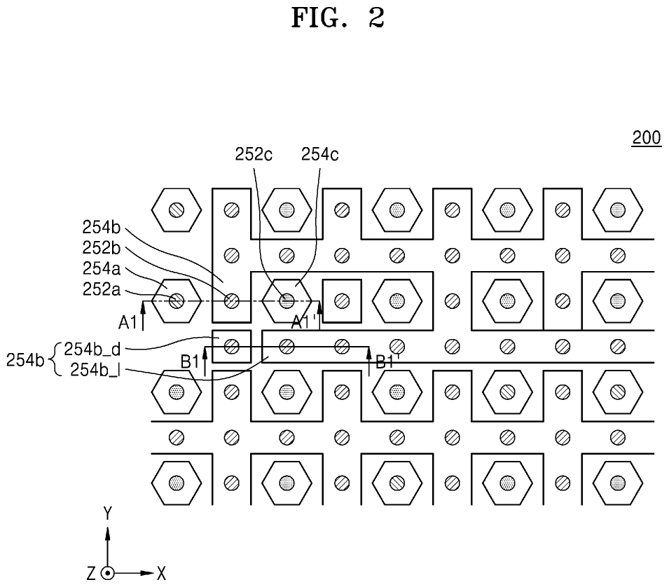

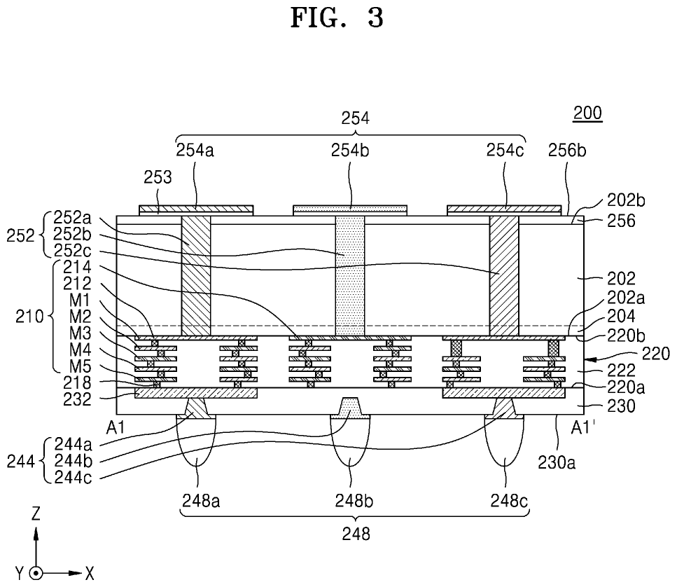

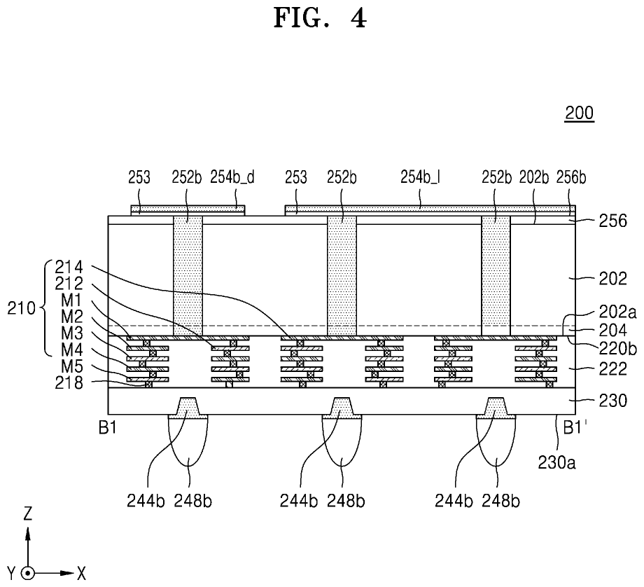

FIG. 1 is a perspective view of a semiconductor chip 200 according to an embodiment. FIG. 2 is a plan view of a semiconductor chip 200 according to an embodiment, and is an enlarged view of region indicated as “EX1” in FIG. 1. FIG. 3 is a cross-sectional view taken along line A1-A1′ in FIG. 2. FIG. 4 is a cross-sectional view taken along line B1-B1′ in FIG. 2.

Referring to FIGS. 1 to 4, the semiconductor chip 200 may include a lower protection layer 230, a multi wiring layer 220, a semiconductor substrate 202, and an upper protection layer 256. According to some embodiments, the semiconductor substrate 202 may include silicon (Si). However, the material of the semiconductor substrate 202 is not limited thereto. For example, the semiconductor substrate 202 may include other semiconductor elements such as germanium (Ge), or compound semiconductors, such as SiC, GaAs, InAs, and InP. The semiconductor substrate 202 may have a silicon on insulator (SOI) structure. For example, the semiconductor substrate 202 may include a buried oxide (BOX) layer. The semiconductor substrate 202 may include a conductive region, for example, a well doped with impurities, or a structure doped with impurities. In addition, the semiconductor substrate 202 may have various device isolation structures such as a shallow trench isolation (STI) structure.

According to embodiments, the semiconductor substrate 202 may include an active surface 202a and an inactive surface 202b opposite thereto. According to embodiments, an integrated device layer 204, in which a plurality of integrated devices are formed, may be arranged on the active surface 202a of the semiconductor substrate 202.

According to embodiments, the integrated elements of the integrated device layer 204 may include memory devices or logic devices. For example, the memory devices may include dynamic random access memory (RAM) (DRAM), static RAM (SRAM), a flash memory, electrically erasable and programmable ROM (EEPROM), phase-change RAM (RRAM), magnetic RAM (MRAM), or resistive RAM (RRAM). For example, the logic devices are AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OAI(OR/AND/INVERTER), AO(AND/OR), AOI(AND/OR/INVERTER), D flip-flop, reset flip-flop, master-slave flip-flop, a latch, a counter, or buffer devices. In addition, the logic devices may include a central processing unit (CPU), a micro-processor unit (MPU), a graphics processing unit (GPU), or an application processor (AP).

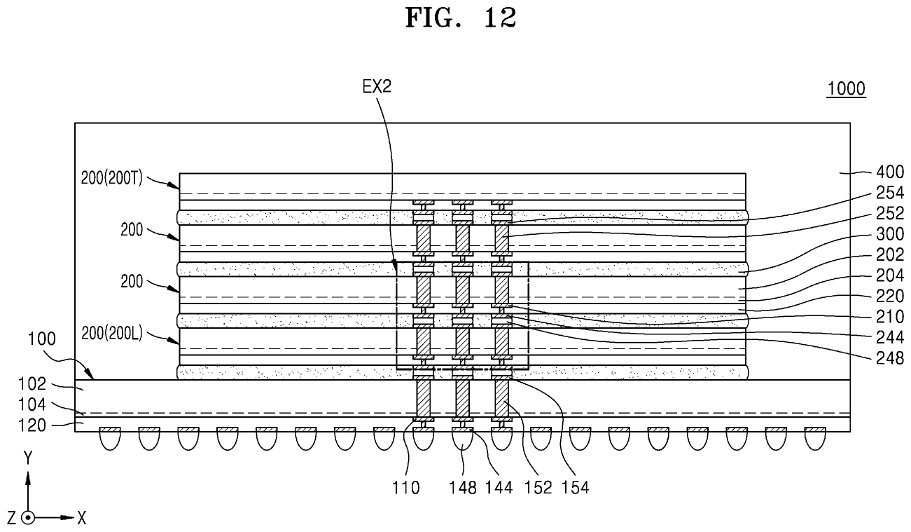

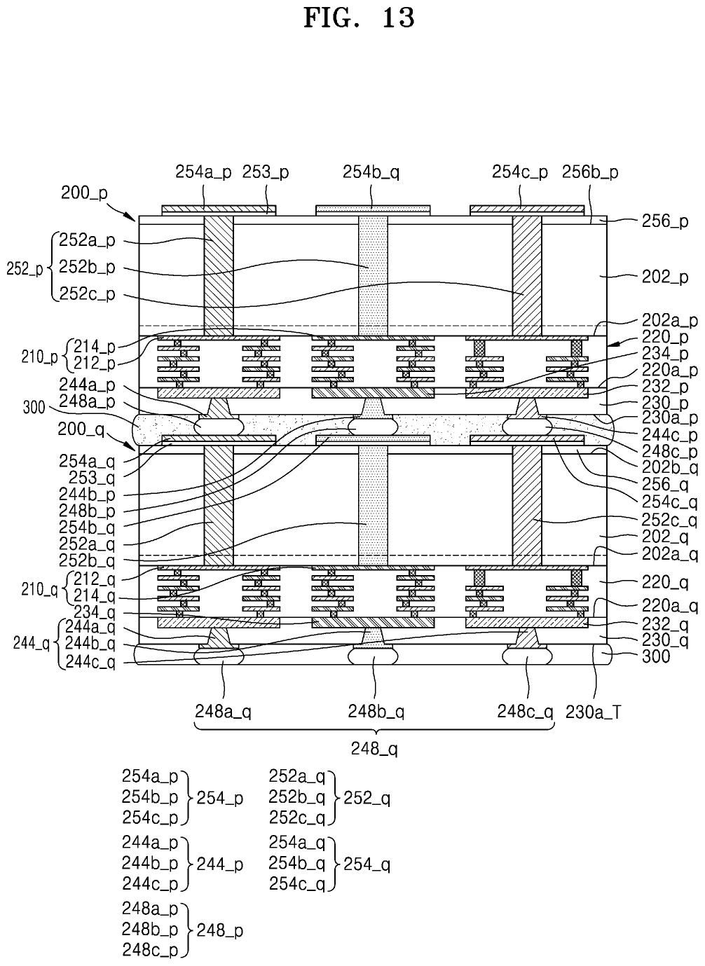

In the semiconductor chip 200 according to embodiments, the integrated device layer 204 may include memory devices, for example, DRAM devices. For example, the semiconductor chip 200 according to embodiments may include a DRAM chip. According to embodiments, the semiconductor chip 200, as a DRAM chip, may be used in a high bandwidth memory (HBM) package. The structure of the HBM package is described below with reference to FIG. 12 and FIG. 13.

According to embodiments, the multi wiring layer 220 may be arranged on the active surface 202a of the semiconductor substrate 202. According to embodiments, the multi wiring layer 220 may include a wiring structure 210 including a conductive wiring 212 and a dummy wiring 214, and an interlayer insulating layer 222.

According to embodiments, the wiring structure 210 may include first through fifth wiring layers M1 through M5 sequentially stacked in a direction away from the active surface 202a of the semiconductor substrate 202, and a wiring via 218 connecting the first through fifth wiring layers M1 through M5 to each other. For example, each of the first through fifth wiring layers M1 through M5 may extend in a horizontal direction (X direction and/or Y direction), and may be positioned at different levels in a vertical direction (Z direction). According to embodiments, the wiring via 218 may be arranged between each of the first through fifth wiring layers M1 through M5, and may extend in the vertical direction (Z direction) to connect between each of the first through fifth wiring layers M1 through M5. According to embodiments, the interlayer insulating layer 222 may surround the wiring structure 210. For example, the interlayer insulating layer 222 may protect the wiring structure 210 and the integrated devices, and may be referred to as a passivation layer. In FIGS. 3 and 4, the multi wiring layer 220 is illustrated to include a wiring layer including five layers, but is not limited thereto. For example, the multi wiring layer 220 may include a wiring layer of two to four layers, and may include a wiring layer of six or more layers. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

According to embodiments, each of the first through fifth wiring layers M1 through M5 and the wiring via 218 may include a metal, such as aluminum (Al), copper (Cu), and tungsten (W), or an alloy thereof. According to embodiments, the interlayer insulating layer 222 may include tetraethyl orthosilicate (TEOS), phosphosilicate glass (PSG), boro-phosphosilicate glass (BPSG), undoped silicate glass (USG), plasma enhanced-TEOS (PE-TEOS), high density plasma-chemical vapor deposition (HDP-CVD), or a combination thereof.

According to embodiments, each of the first to fifth wiring layers M1, M2, M3, M4, and M5 may constitute at least a portion of the conductive wiring 212 and/or the dummy wiring 214. According to embodiments, the conductive wiring 212 may be electrically connected to an integrated device of the integrated device layer 204, and provide a transfer path of an input/output signal and power of the integrated circuit. For example, the power may mean a ground voltage applied to an integrated circuit device and a power voltage for power supply. According to embodiments, the dummy wiring 214 may be distinguished from the conductive wiring 212, and may include a floated wiring. For example, the dummy wiring 214 may be arranged near the conductive wiring 212 without a routing purpose, and uniformize wiring density for each position of the multi wiring layer 220. For example, the dummy wiring 214 may be arranged near the conductive wiring 212, and discharge heat generated by the conductive wiring 212 in the horizontal direction (X direction and/or Y direction) or the vertical (Z direction).

According to embodiments, a conductive medium pad 232 connected to the wiring structure 210 may be arranged on a front surface 220a of the multi wiring layer 220. According to embodiments, the conductive medium pad 232 may be connected to a lowermost wiring layer (for example, the fifth wiring layer M5) of the wiring structure 210 via the wiring via 218. According to embodiments, the lower protection layer 230 covering the conductive medium pad 232 may be arranged on the front surface 220a of the multi wiring layer 220. For example, the conductive medium pad 232 may be arranged in the lower protection layer 230, and the lower protection layer 230 may protect the wiring structure 210 and the conductive medium pad 232. According to embodiments, the conductive medium pad 232 may have a dot shape covering the wiring via 218, but is not limited thereto. For example, the conductive medium pad 232 may also have a line shape extending in the horizontal direction (X direction and/or Y direction). The back surface 220b of the multi wiring layer 220 may contact the integrated device layer 204.

According to embodiments, the conductive medium pad 232 may include a metal, such as Al, Cu, and W, or an alloy thereof. According to embodiments, the lower protection layer 230 may include tetraethyl orthosilicate (TEOS), phosphosilicate glass (PSG), boro-phosphosilicate glass (BPSG), undoped silicate glass (USG), plasma enhanced-TEOS (PE-TEOS), high density plasma-chemical vapor deposition (HDP-CVD), or a combination thereof.

According to embodiments, the plurality of front side pads 244 may be arranged on a front surface 230a of the lower protection layer 230. According to embodiments, the plurality of front side pads 244 may include a plurality of front side power pads 244a for providing a power voltage transfer path to an integrated circuit, a plurality of front side dummy pads 244b for heat dissipation of the semiconductor chip 200, and a plurality of front side signal pads 244c for providing an input/output signal transfer path to an integrated circuit. According to embodiments, the plurality of front side power pads 244a and the plurality of front side signal pads 244c may penetrate a portion of the lower protection layer 230 to be connected to the conductive medium pad 232, and may be exposed to the front surface 230a of the lower protection layer 230. According to embodiments, the number of the conductive medium pad 232 may be plural, and each of the plurality of front side power pads 244a and the plurality of front side signal pads 244c may be connected to different conductive medium pads 232. According to embodiments, each of the plurality of front side power pads 244a and the plurality of front side signal pads 244c may be connected to the conductive wiring 212 via the conductive medium pad 232.

According to embodiments, the plurality of front side pads 244 may include nickel (Ni), Al, Cu, gold (Au), silver (Ag), platinum (Pt), W, titanium (Ti), or an alloy thereof.

According to embodiments, a plurality of external connection terminals 248 may be attached to the plurality of front side pads 244. According to embodiments, the plurality of external connection terminals 248 may include a plurality of power connection terminals 248a respectively connected to the plurality of front side power pads 244a, a plurality of dummy connection terminals 248b respectively connected to the plurality of front side dummy pads 244b, and a plurality of signal connection terminals 248c respectively connected to the plurality of front side signal pads 244c. According to embodiments, the plurality of dummy connection terminals 248b may discharge heat transferred from the plurality of front side dummy pads 244b to the outside. In FIGS. 3 and 4, all sizes of a plurality of external connection terminals 248 are illustrated as the same, but are not limited thereto. For example, sizes of the plurality of dummy connection terminals 248b may be less than sizes of the plurality of power connection terminals 248a or the plurality of signal connection terminals 248c. According to embodiments, the plurality of external connection terminals 248 may include a conductive pillar, a bump, a solder ball, etc.

According to embodiments, the upper protection layer 256 may be arranged on the inactive surface 202b of the semiconductor substrate 202. According to embodiments, the upper protection layer 256 may include TEOS, PSG, BPSG, USG, PE-TEOS, HDP-CVD, or a combination thereof.

According to embodiments, the semiconductor chip 200 may include a plurality of through vias 252 penetrating the semiconductor substrate 202 and the upper protection layer 256. According to embodiments, the plurality of through vias 252 may include a plurality of power through vias 252a for providing a power voltage transfer path to an integrated circuit, a plurality of dummy through vias 252b for providing a heat dissipation path of the semiconductor chip 200, and a plurality of signal through vias 252c for providing an input/output signal transfer path to an integrated circuit.

According to embodiments, a plurality of through vias 252 may be connected to the wiring structure 210 of the multi wiring layer 220. For example, each of the plurality of power through vias 252a, the plurality of dummy through vias 252b, and the plurality of signal through vias 252c may be connected to the wiring structure 210. According to embodiments, the plurality of through vias 252 may be connected to the uppermost wiring layer of the wiring structure 210 (for example, the first wiring layer M1).

According to embodiments, each of the plurality of power through vias 252a and the plurality of signal through vias 252c may be connected to the conductive wiring 212, and the plurality of dummy through vias 252b may be connected to the dummy wiring 214. According to embodiments, the plurality of power through vias 252a and the plurality of signal through vias 252c may be connected to the conductive wiring 212 on the first wiring layer M1, and the plurality of dummy through vias 252b may be connected to the dummy wiring 214 on the first wiring layer M1.

The semiconductor chip 200 according to embodiments may include a structure, in which the plurality of dummy through vias 252b are connected to the dummy wiring 214, and accordingly, heat dissipation characteristics of the semiconductor chip 200 in the vertical direction (Z direction) may be improved.

Referring to FIG. 2, at least one of the plurality of dummy through vias 252b may be arranged between two signal through vias 252c of the plurality of signal through vias 252c in a plan view. For example, at least one of the plurality of dummy through vias 252b may be arranged between two adjacent signal through vias 252c. For example, the two signal through vias 252c of the plurality of signal through vias 252c may be apart from each other with a dummy through via 252b therebetween. According to exemplary embodiments, the plurality of dummy through vias 252b may be arranged to surround the plurality of signal through vias 252c in a plan view. For example, the plurality of dummy through vias 252b may be arranged to surround each signal through via 252c. Accordingly, signal interference occurring between signal through vias 252c arranged adjacent to each other of the plurality of signal through vias 252c may be prevented, and parasitic capacitance may be removed. Thus, the electrical reliability of the semiconductor chip 200 may be improved.

In FIG. 2, the plurality of signal through vias 252c are illustrated to be respectively surrounded by the plurality of dummy through vias 252b, but are not limited thereto. For example, the plurality of dummy through vias 252b may be arranged to surround two or more signal through vias 252c together, and in this case, the dummy through via 252b may not also be arranged between the two or more signal through vias 252c surrounded together.

According to embodiments, each of the plurality of through vias 252 may include Cu, CuSn, CuMg, CuNi, CuZn, CuPd, CuAu, CuRe, CuW, W, or a W alloy, but is not limited thereto. For example, each of the plurality of through vias 252 may include one or more of Al, Au, beryllium (Be), bismuth (Bi), cobalt (Co), Cu, hafnium (Hf), indium (In), manganese (Mn), molybdenum (Mo), Ni, lead (Pb), palladium (Pd), Pt, rhodium (Rh), rhenium (Re), ruthenium (Ru), Ta, tellurium (Te), Ti, W, zinc (Zn), and zirconium (Zr), and may include two or more stacked structures. For example, the plurality of through vias 252 may include at least one material of tungsten nitride (WN), tungsten carbide (WC), Ti nitride (TiN), Ta nitride (TaN), or nickel boron (NiB), but is not limited thereto.

According to embodiments, the semiconductor chip 200 may include a plurality of back side pads 254 arranged on a rear surface 256b of the upper protection layer 256, and respectively connected to the plurality of through vias 252. According to embodiments, the plurality of back side pads 254 may include a plurality of back side power pads 254a respectively connected to the plurality of power through vias 252a, a plurality of back side dummy pads 254b respectively connected to the plurality of dummy through vias 252b, and a plurality of back side signal pads 254c respectively connected to the plurality of signal through vias 252c. According to embodiments, a pad seed layer 253 may be arranged between the plurality of through vias 252 and the plurality of back side pads 254.

According to embodiments, each of the plurality of back side power pads 254a and the plurality of back side signal pads 254c may have a dot shape. For example, in a plan view, each of the plurality of back side power pads 254a and the plurality of back side signal pads 254c may have an independent island shape. According to embodiments, the plurality of back side dummy pads 254b may include a dot pad 254b_d having a dot shape and a line pad 254b_1 having a line shape. For example, the dot pad 254b_d may be connected to one dummy through via 252b, and in a plan view, may have an independent island shape. For example, the line pad 254b_1 may be connected to two or more dummy through vias 252b, and may have a line shape extending in the horizontal direction (X direction and/or Y direction). According to embodiments, the plurality of back side dummy pads 254b may be arranged on the plurality of dummy through vias 252b, the heat dissipation characteristics of the semiconductor chip 200 in the vertical direction (Z direction) may be improved, and heat dissipation in the horizontal direction (X direction and/or Y direction) may be induced by using the line pad 254b_1 extending in the horizontal direction (X direction and/or Y direction).

According to embodiments, in a plan view, at least one of the plurality of back side dummy pads 254b may be arranged between two back side signal pads 254c of the plurality of back side signal pads 254c. For example, at least one of the plurality of back side dummy pads 254b may be arranged between two adjacent back side signal pads 254c. According to embodiments, two back side signal pads 254c of the plurality of back side signal pads 254c may be apart from each other with the back side dummy pad 254b therebetween. According to embodiments, the line pad 254b_1 may be arranged to surround the back side signal pad 254c in a plan view. For example, the line pad 254b_1 may extend between the plurality of back side signal pads 254c, and in a plan view, may be arranged to surround at least one of the plurality of back side signal pads 254c. Accordingly, signal interference between the plurality of back side signal pads 254c may be reduced, and the electrical reliability of the semiconductor chip 200 may be improved.

According to embodiments, each of the plurality of back side pads 254 may include Ni, Al, Cu, Au, Ag, Pt, W, Ti, or an alloy thereof. According to embodiments, the pad seed layer 253 may include Cu, Ti, titanium tungsten (TiW), TiN, Ta, TaN, chromium (Cr), and Al.

According to embodiments, the second wiring layer M2 may not include a portion overlapping the back side signal pad 254c and the signal through via 252c in the vertical direction (Z direction). For example, the signal through via 252c may not overlap the second wiring layer M2 in the vertical direction (Z direction). In this case, the first wiring layer M1 arranged under the signal through via 252c may be connected to the third wiring layer M3 via the wiring via 218. Accordingly, the structural stability and electrical reliability of the wiring structure 210 may be improved.

In FIG. 2, the plurality of back side power pads 254a and the plurality of back side signal pads 254c are illustrated to have hexagonal planar shapes, but are not limited thereto. For example, each of the plurality of back side power pads 254a and the plurality of back side signal pads 254c may have other planar shapes, such as a circular shape and a rectangular shape. In FIG. 2, the plurality of dot pads 254b_d are illustrated to have a rectangular planar shape, but are not limited thereto. For example, the plurality of dot pads 254b_d may have a planar shape of a circle, a hexagon, etc. FIG. 2 illustrates an example arrangement relationship between the plurality of back side power pads 254a, the plurality of back side dummy pads 254b, and the plurality of back side signal pads 254c, but aspects of the inventive concept are not limited thereto.

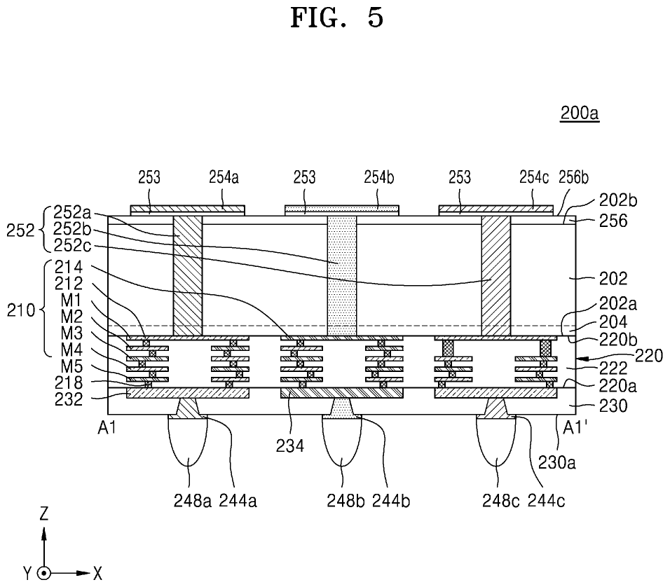

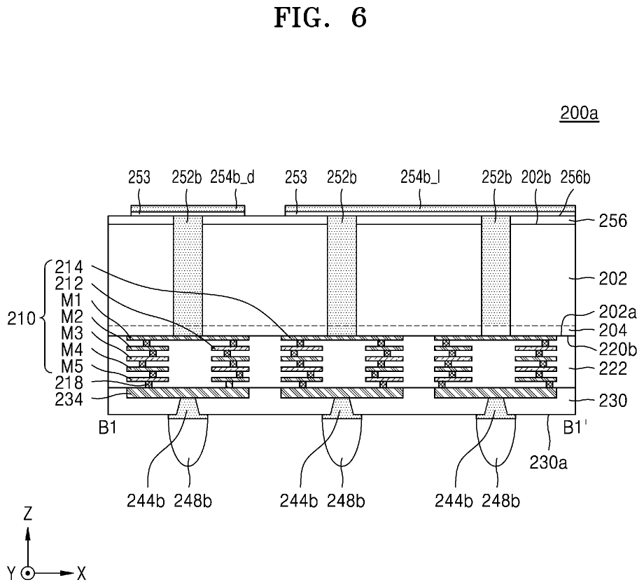

FIG. 5 is a cross-sectional view taken along line A1-A1′ of a semiconductor chip 200a, according to other embodiments having a plan view of FIG. 2. FIG. 6 is a cross-sectional view taken along line B1-B1′ of the semiconductor chip 200a, according to other embodiments having the plan view of FIG. 2. The difference between FIGS. 5 and 6 and FIGS. 3 and 4 may be whether the semiconductor chip 200 further includes a dummy medium pad 234.

Referring to FIGS. 5 and 6, the dummy medium pad 234 may be arranged on the front surface 220a of the multi wiring layer 220, and connected to the wiring structure 210. According to embodiments, the dummy medium pad 234 may be connected to the lowermost wiring layer (for example, the fifth wiring layer M5) of the wiring structure 210 via the wiring via 218. According to embodiments, the dummy medium pad 234 may be covered by the lower protection layer 230. According to embodiments, the dummy medium pad 234 may have a dot shape or a line shape extending in the horizontal direction (X direction/Y direction).

According to embodiments, the number of dummy medium pads 234 may be in plural, and each of the plurality of front side dummy pads 244b may be connected to the dummy medium pad 234. Accordingly, heat may be transferred between the dummy wiring 214 and the front side dummy pad 244b via the dummy medium pad 234, and the heat dissipation characteristics of the semiconductor chip 200a may be improved. According to embodiments, each of the plurality of front side dummy pads 244b may be connected to the dummy wiring 214 via the dummy medium pad 234.

According to embodiments, the back side dummy pad 254b, the dummy through via 252b, the dummy wiring 214, the dummy medium pad 234, the front side dummy pad 244b, and the dummy connection terminal 248b may provide the heat dissipation path of the semiconductor chip 200a in the vertical (Z direction). Accordingly, heat generated during an operation of the semiconductor chip 200a may be easily discharged to the outside, and accordingly, the reliability of the semiconductor chip 200a may be improved.

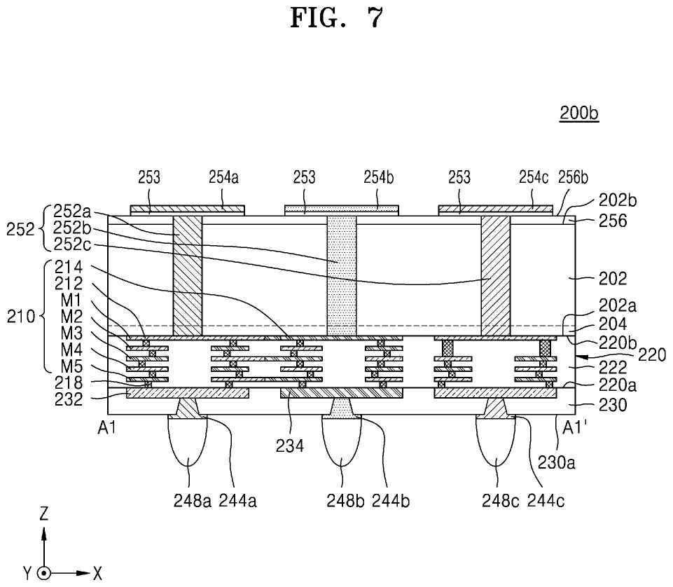

FIG. 7 is a cross-sectional view taken along line A1-A1′ of a semiconductor chip 200b, according to other embodiments having the plan view of FIG. 2. The difference between FIG. 7 and FIG. 5 is whether the conductive wiring 212 is connected to the dummy wiring 214.

Referring to FIG. 7, the dummy wiring 214 may be connected to the conductive wiring 212. According to embodiments, the dummy wiring 214 may, as a wiring with one end thereof floating from a circuit point of view, be connected to the conductive wiring 212, and provide an additional heat dissipation path to the conductive wiring 212 without hindering the electrical characteristics of the semiconductor chip 200b. For example, the conductive wiring 212 may contact the dummy wiring 214 in a horizontal direction (e.g., X direction and/or Y direction).

According to embodiments, the dummy wiring 214 and the conductive wiring 212 may be connected to each other in lower regions of the power through via 252a and dummy through via 252b, which are adjacent to each other. In this case, the lower regions of the power through via 252a and the dummy through via 252b may mean a first region, where a portion of the multi wiring layer 220 overlaps the power through via 252a in the vertical direction (Z direction), a second region, where a portion of the multi wiring layer 220 overlaps the dummy through via 252b, and a region between the first region and the second region.

According to embodiments, the conductive wiring 212 and the dummy wiring 214 connected to each other may have an integrated structure. For example, the conductive wiring 212 and the dummy wiring 214 connected to each other may include the same material. According to embodiments, each of the first through fifth wiring layers M1 through M5 may include different materials. For example, the first wiring layer M1 and the second wiring layer M2 may include A1, and the third wiring layer M3, the fourth wiring layer M4, and the fifth wiring layer M5 may include Cu. For example, the conductive wiring 212 and the dummy wiring 214, which respectively constitute wiring layers and are connected to each other, may include the same material.

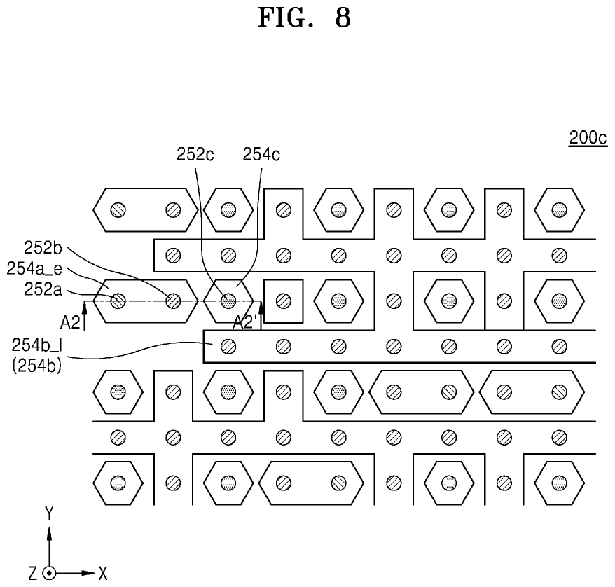

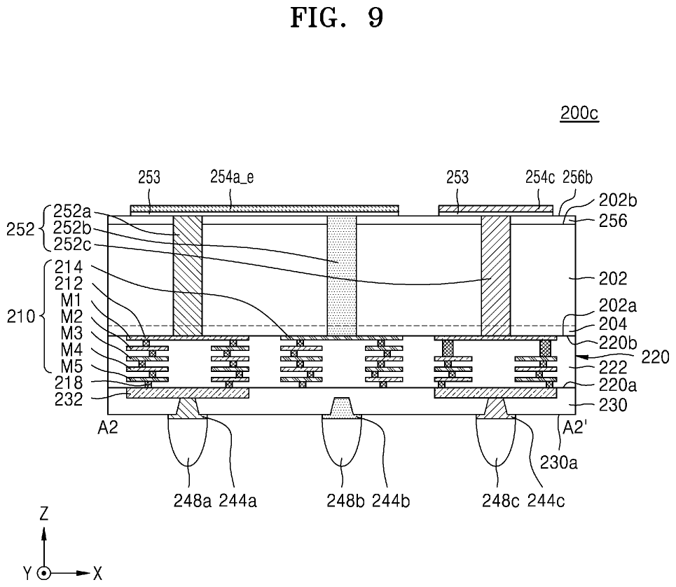

FIG. 8 is a plan view of a semiconductor chip 200c according to some other embodiments, and is an enlarged view of region indicated as “EX1” in FIG. 1. FIG. 9 is a cross-sectional view taken along line A2-A2′ in FIG. 8. The difference between FIGS. 8 and 9 and FIGS. 2 and 3 may be whether the semiconductor chip 200c includes a back side expansion pad 254a_e connected together with the power through via 252a and the dummy through via 252b.

Referring to FIGS. 8 and 9, the semiconductor chip 200c may include a plurality of back side expansion pads 254a_e arranged on the rear surface 256b of the upper protection layer 256, and connected together with at least one of the plurality of power through vias 252a and the plurality of dummy through vias 252b, which are adjacent to each other. For example, at least one of the plurality of power through vias 252a may be connected to at least one of the plurality of dummy through vias 252b via the back side expansion pad 254a_e. According to embodiments, the plurality of back side expansion pads 254a_e may have a greater plan area than the plurality of back side power pads 254a and the plurality of back side dummy pads 254b described above, and accordingly, may improve the heat dissipation characteristics in the horizontal direction (X direction and/or Y direction). According to embodiments, the plurality of back side expansion pads 254a_e may provide a heat dissipation path in the horizontal direction (X direction and/or Y direction) between the plurality of power through vias 252a and the plurality of dummy through vias 252b. In addition, the plurality of dummy through vias 252b may be respectively arranged between each of the plurality of signal through vias 252c, respectively connected to the plurality of power through vias 252a via the plurality of back side expansion pads 254a_e. Such an arrangement may prevent interference between signals inside a circuit, and accordingly, may improve the reliability of the semiconductor chip 200c. For example, the plurality of back side expansion pads 254a_e may not be connected to the plurality of signal through vias 252c.

According to embodiments, the plurality of back side expansion pads 254a_e may include Ni, Al, Cu, Au, Ag, Pt, W, Ti, or an alloy thereof.

In FIG. 9, each of all the plurality of power through vias 252a are illustrated to be connected to the back side expansion pad 254a_e, but is not limited thereto. For example, some of the plurality of power through vias 252a may be connected to the back side power pad 254a (refer to FIGS. 2 and 3), and the other thereof may be connected to the back side expansion pad 254a_e. In addition, in FIG. 9, one power through via 252a and one dummy through via 252b are illustrated to be connected to one back side expansion pad 254a_e, but the embodiment is not limited thereto. For example, one power through via 252a and two or more dummy through vias 252b may be connected to one back side expansion pad 254a_e, two or more power through vias 252a and one dummy through via 252b may be connected to one back side expansion pad 254a_e, and two or more power through vias 252a and two or more dummy through vias 252b may be connected to one back side expansion pad 254a_e.

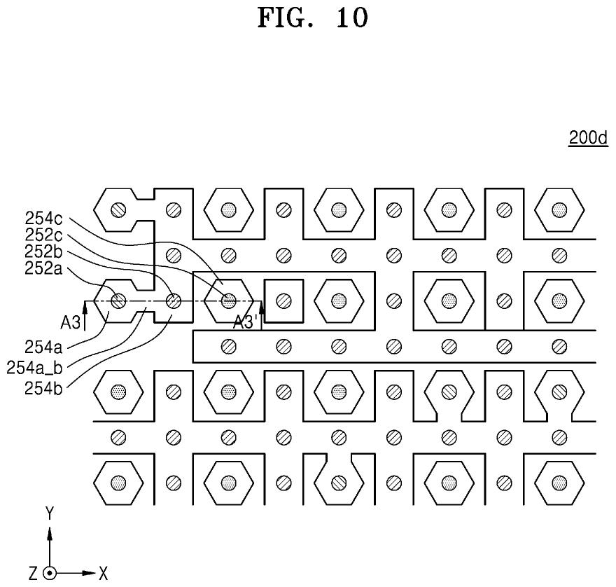

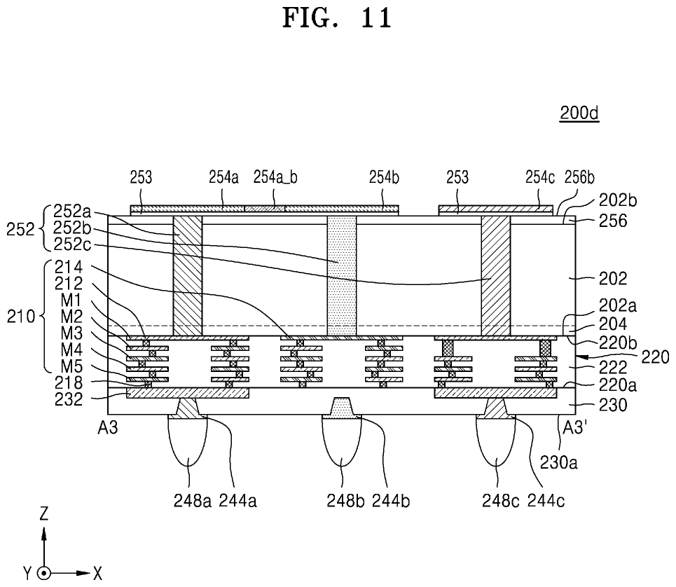

FIG. 10 is a plan view of a semiconductor chip 200d according to some other embodiments, and is an enlarged view of region indicated as “EX1” in FIG. 1. FIG. 11 is a cross-sectional view taken along line A3-A3′ in FIG. 10. The difference between FIGS. 10 and 11 and FIGS. 2 and 3 may be whether the back side power pad 254a and the back side dummy pad 254b are connected to each other.

Referring to FIGS. 10 and 11, at least one of the plurality of back side power pads 254a may be connected to at least one of the plurality of back side dummy pads 254b via a back side bridge 254a_b. In FIGS. 10 and 11, the back side bridge 254a_b is illustrated to connect the back side power pad 254a to the back side dummy pad 254b, but the back side bridge 254a_b may also be arranged to connect the plurality of back side power pads 254a to each other. According to embodiments, the back side bridge 254a_b may be arranged not to connect the plurality of back side signal pads 254c to the plurality of back side power pads 254a, and may be arranged not to connect the plurality of back side signal pads 254c to the plurality of back side dummy pads 254b. For example, the back side bridge 254a_b may provide a heat dissipation path between the plurality of back side power pads 254a and the plurality of back side dummy pads 254b, and accordingly, the heat dissipation characteristics of the semiconductor chip 200d in the horizontal direction (X direction and/or Y direction) may be improved. In addition, the plurality of back side dummy pads 254b arranged to respectively surround the plurality of back side signal pads 254c may be respectively connected to the plurality of back side power pads 254a via the back side bridge 254a_b, and signal interference during an operation of the semiconductor chip 200d may be prevented.

According to embodiments, the back side bridge 254a_b may have an integral structure with the back side power pad 254a and the back side dummy pad 254b, which are connected to the back side bridge 254a_b. According to embodiments, the back side bridge 254a_b may include the same material as the plurality of back side power pads 254a and the plurality of back side dummy pads 254b. According to embodiments, the plurality of back side bridge 254a_b may include Ni, Al, Cu, Au, Ag, Pt, W, Ti, or an alloy thereof.

FIG. 12 is a cross-sectional view of a semiconductor package 1000 according to an embodiment. FIG. 13 is an enlarged view of region indicated by “EX2” in FIG. 12. FIG. 13 may correspond to a portion corresponding to a cross-sectional view taken along line A1-A1′ in the plan view of FIG. 2. Descriptions already given with reference to FIGS. 1 through 11 are briefly described or omitted. For example, as described with reference to FIGS. 2, 8, and 10, it may be clearly understood that the numbers of through vias, back side pads, front side pads, or the like may be formed in plural, and the planar arrangement relationship between respective components may be understood. Hereinafter, the semiconductor chips 200, 200a, 200b, 200c, and 200d according to the embodiments described above may be referred to as buffer chips or core chips, the multi wiring layer 220 may be referred to as a wiring layer, and the front and rear surfaces thereof may be referred to as lower and upper surfaces thereof, respectively.

Referring to FIG. 12, the semiconductor package 1000 may include a buffer chip 100, a core chip 200 on the buffer chip 100, and a sealing material 400. Although in FIG. 12, four core chips 200 are illustrated arranged on the buffer chip 100, the embodiment is not limited thereto. For example, one core chip 200 may be arranged on the buffer chip 100, and two or more core chips 200 may be stacked on the buffer chip 100.

According to embodiments, the buffer chip 100 may have a size greater than that of the core chip 200 arranged thereon. However, the embodiment is not limited thereto, and the buffer chip 100 may also have substantially the same size as the core chip 200. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

According to embodiments, the buffer chip 100 may include a semiconductor substrate 102, an integrated device layer 104, a wiring layer 120, a wiring structure 110 in the wiring layer 120, a plurality of front side pads 144, a plurality of external connection terminals 148, a plurality of through vias 152, and a plurality of back side pads 154. According to embodiments, the semiconductor substrate 102 may include a silicon substrate. However, the semiconductor substrate 102 is not limited to silicon substrates and may include other semiconductor elements such as germanium (Ge), or compound semiconductors such as, silicon carbide (SiC), gallium arsenide (GaAs), indium arsenide (InAs), and indium phosphide (InP).

According to embodiments, the integrated device layer 104 may include a plurality of logic devices. Accordingly, the buffer chip 100 may be referred to as a logic chip or a control chip. The buffer chip 100 may be arranged under the core chip 200, integrate and transfer to the outside the signals of the core chip 200, and in addition, transfer the signals and power from the outside to the core chip 200. For example, the buffer chip 100 may also include a buffer memory device and a general memory device.

According to embodiments, the wiring layer 120 may include the wiring structure 110 arranged under the semiconductor substrate 102 and including two or more wiring layers therein. According to embodiments, the plurality of front side pads 144 may be arranged below the semiconductor substrate 102, and the plurality of external connection terminals 148 may be respectively attached to lower surfaces of the plurality of front side pads 144.

According to embodiments, the plurality of through vias 152 may at least partially penetrate the semiconductor substrate 102. The plurality of through vias 152 of the buffer chip 100 may correspond to the plurality of through vias 252 of the semiconductor chip 200 described with reference to FIGS. 3 and 4. For example, the plurality of through vias 152 may include a plurality of power through vias, a plurality of dummy through vias, and a plurality of signal through vias.

According to embodiments, a lower surface of each of the plurality of through vias 152 may be connected to the wiring structure 110, and upper surfaces of the plurality of through vias 152 may be respectively connected to the plurality of back side pads 154. For example, the plurality of back side pads 154 may correspond to the plurality of back side pads 254 described with reference to FIGS. 3 and 4. For example, the plurality of back side pads 154 may, according to the type of the plurality of through vias 152 respectively connected thereto, be classified into a plurality of back side power pads, a plurality of back side dummy pads, or a plurality of back side signal pads.

The wiring layer 120, the wiring structure 110, the plurality of front side pads 144, the plurality of through vias 152, and the plurality of back side pads 154 of the buffer chip 100 may respectively correspond to the multi wiring layer 220, the wiring structure 210, the plurality of front side pads 244, the plurality of through vias 252, and the plurality of back side pads 254 of the semiconductor chips 200, 200a, 200b, 200c, and 200d described with reference to FIGS. 1 through 11.

According to embodiments, a plurality of core chips 200 may correspond to the semiconductor chips 200, 200a, 200b, 200c, and 200d described with reference to FIGS. 1 through 11. According to embodiments, the plurality of core chips 200 may include the semiconductor substrate 202, the multi wiring layer 220, the wiring structure 210, the plurality of front side pads 244, the plurality of external connection terminals 248, the plurality of through vias 252, and the plurality of back side pads 254.

According to embodiments, a lowermost core chip 200L arranged at the lowest end of the plurality of core chips 200 may be electrically connected to the buffer chip 100 via the plurality of external connection terminals 248 respectively connected to the plurality of back side pads 154 of the buffer chip 100. According to embodiments, an adhesive layer 300 may be arranged between the lowermost core chip 200L and the buffer chip 100. According to embodiments, the adhesive layer 300 may cover a lower surface of the lowest core chip 200L and at least a portion of an upper surface of the buffer chip 100, a lower surface of the plurality of front side pads 244 of the lowest core chip 200L, the external connection terminal 248, and an upper surface of the plurality of back side pads 154 of the buffer chip 100.

According to embodiments, the plurality of core chips 200 may be connected to each other via the external connection terminal 248, and the adhesive layer 300 may be arranged between each of the plurality of core chips 200. Hereinafter, a portion, to which a plurality of core chips 200 are connected, is described in detail with reference to FIG. 13. The core chip 200 arranged at a lower portion of two core chips 200 connected to each other may be referred to as a lower semiconductor chip or a first semiconductor chip, and the core chip 200 arranged at an upper portion thereof may be referred to as an upper semiconductor chip or a second semiconductor chip. Structures of the components of each of the first and second semiconductor chips and the arrangement relationship between the components thereof may be similar to the structures of the components and the arrangement relationship between the components of the semiconductor chips 200, 200a, 200b, 200c, and 200d described above with reference to FIGS. 1 through 12.

According to embodiments, a second semiconductor chip 200_p may be arranged on the first semiconductor chip 200_q. According to embodiments, the first semiconductor chip 200_q may include a first semiconductor substrate 202_q including an active surface 202a_q and an inactive surface 202b_q opposite thereto, a first multi wiring layer 220_q on the active surface 202a_q of first semiconductor substrate 202_q, and a first lower protection layer 230_q on the active surface 220a_q of the first multi wiring layer 220_q, and a first upper protection layer 256_q on the inactive surface 202b_q of the first semiconductor substrate 202_q.

According to embodiments, a first wiring structure 210_q including a first conductive wiring 212_q and a first dummy wiring 214_q may be arranged in the first multi wiring layer 220_q. According to embodiments, a first dummy medium pad 234_q and a first conductive medium pad 232_q connected to the first wiring structure 210_q may be arranged in the first lower protection layer 230_q.

According to embodiments, a plurality of first connection terminals 248_q may be connected to the first dummy medium pad 234_q or the first conductive medium pad 232_q may be arranged on a front surface 230a_q of the first lower protection layer 230_q. The plurality of first connection terminals 248_q may include a first power connection terminal 248a_q, a first dummy connection terminal 248b_q, and a first signal connection terminal 248c_q. According to embodiments, a plurality of first front side pads 244_q may include a plurality of first front side power pads 244a_q, a plurality of first front side dummy pads 244b_q, and a plurality of first front side signal pads 244c_q. According to embodiments, the first power connection terminal 248a_q may be attached to each of the plurality of first front side power pads 244a_q, the first dummy connection terminal 248b_q may be attached to each of the plurality of first front side dummy pads 244b_q, and the first signal connection terminal 248c_q may be attached to each of the plurality of first front side signal pads 244c_q.

According to embodiments, the first semiconductor chip 200_q may include a plurality of first through vias 252_q penetrating the first semiconductor substrate 202_q and the first upper protection layer 256_q. According to embodiments, the plurality of first through vias 252_q may include a plurality of first power through vias 252a_q, a plurality of first dummy through vias 252b_q, and a plurality of first signal through vias 252c_q. According to embodiments, each of the plurality of first power through vias 252a_q and the plurality of first signal through vias 252c_q may be connected to the first conductive wiring 212_q, and the plurality of first dummy through vias 252b_q may be connected to the first dummy wiring 214_q.

A planar arrangement relationship between the plurality of first through vias 252_q and a plurality of first back side pads 254_q to be described below may be understood with reference to the plan view of FIG. 2. For example, the cross-sectional view of FIG. 13 may have a structure similar to that of the cross-section taken along line A1-A1′ in the plan view of FIG. 2.

According to embodiments, in a plan view, at least one of the plurality of first dummy through vias 252b_q may be arranged between the plurality of first signal through vias 252c_q. According to embodiments, in a plan view, at least one of the plurality of first dummy through vias 252b_q may be arranged between two first signal through vias 252c_q of the plurality of first signal through vias 252c_q. According to embodiments, in a plan view, the plurality of first dummy through vias 252b_q may be arranged to surround any one of the plurality of first signal through vias 252c_q.

According to embodiments, the plurality of first back side pads 254_q respectively connected to the plurality of first through vias 252_q may be arranged on the first upper protection layer 256_q. According to embodiments, the plurality of first back side pads 254_q may include a plurality of first back side power pads 254a_q respectively connected to the plurality of first power through vias 252a_q, a plurality of first back side dummy pads 254b_q respectively connected to the plurality of first dummy through vias 252b_q, and a plurality of first back side signal pads 254c_q respectively connected to the plurality of first signal through vias 252c_q.

According to embodiments, in a plan view, at least one of the plurality of first back side dummy pads 254b_q may be arranged between each of the plurality of first back side signal pads 254c_q. According to embodiments, in a plan view, at least one of the plurality of first back side dummy pads 254b_q may be arranged between two first back side signal pads 254c_q of the plurality of first back side signal pads 254c_q. According to embodiments, in a plan view, the plurality of first back side dummy pads 254b_q may be arranged to surround any one of the plurality of first back side signal pads 254c_q.

According to embodiments, the plurality of first back side dummy pads 254b_q may include the dot pad 254b_d of a dot shape (refer to FIG. 2) and a line pad 254b_1 of a line shape (refer to FIG. 2). According to embodiments, the dot pad 254b_d may be connected to one first dummy through via 252b_q, and the line pad 254b_1 may be connected to two or more first dummy through vias 252b_q. According to embodiments, in a plan view, the line pad 254b_1 may be arranged to surround at least one of the plurality of first back side signal pads 254c_q.

According to embodiments, the second semiconductor chip 200_p may include a second semiconductor substrate 202_p including an active surface 202a_p and an inactive surface 202b_p opposite thereto, a second multi wiring layer 220_p on the active surface 202a_p of the second semiconductor substrate 202_p, and a second lower protection layer 230_p on the front surface 220a_p of the second multi wiring layer 220_p, and a second upper protection layer 256_p on the inactive surface 202b_p of the second semiconductor substrate 202_p.

According to embodiments, a second wiring structure 210_p including a second conductive wiring 212_p and a second dummy wiring 214_p may be arranged in the second multi wiring layer 220_p. According to embodiments, a second dummy medium pad 234_p and a second conductive medium pad 232_p connected to the second wiring structure 210_p may be arranged in the second lower protection layer 230_p.

According to embodiments, a plurality of second connection terminals 248_p may be connected to the second dummy medium pad 234_p or the second conductive medium pad 232_p may be arranged on a front surface 230a_p of the second lower protection layer 230_p. The plurality of second connection terminals 248_p may include a second power connection terminal 248a_p, a second dummy connection terminal 248b_p, and a second signal connection terminal 248c_p. According to embodiments, a plurality of second front side pads 244_p may include a plurality of second front side power pads 244a p, a plurality of second front side dummy pads 244b_p, and a plurality of second front side signal pads 244c_p. According to embodiments, the second power connection terminal 248a_p may be attached to each of the plurality of second front side power pads 244a_p, the second dummy connection terminal 248b_p may be attached to each of the plurality of second front side dummy pads 244b_p, and the second signal connection terminal 248c_p may be attached to each of the plurality of second front side signal pads 244c_p.

According to embodiments, the second semiconductor chip 200_p may include a plurality of second through vias 252_p penetrating the second semiconductor substrate 202_p and the second upper protection layer 256_p. According to embodiments, the plurality of second through vias 252_p may include a plurality of second power through vias 252a_p, a plurality of second dummy through vias 252b_p, and a plurality of second signal through vias 252c_p. According to embodiments, each of the plurality of second power through vias 252a_p and the plurality of second signal through vias 252c_p may be connected to the second conductive wiring 212_p, and the plurality of second dummy through vias 252b_p may be connected to the second dummy wiring 214_p.

A planar arrangement relationship between the plurality of second through vias 252_p and a plurality of second back side pads 254_p to be described below may be understood with reference to the plan view of FIG. 2. For example, the cross-sectional view of FIG. 13 may have a structure similar to that of the cross-section taken along line A1-A1′ in the plan view of FIG. 2.

According to embodiments, in a plan view, at least one of the plurality of second dummy through vias 252b_p may be arranged between the plurality of second signal through vias 252c_p. According to embodiments, in a plan view, at least one of the plurality of second dummy through vias 252b_p may be arranged between two second signal through vias 252c_p of the plurality of second signal through vias 252c_p. According to embodiments, in a plan view, the plurality of second dummy through vias 252b_p may be arranged to surround any one of the plurality of second signal through vias 252c_p.

According to embodiments, the plurality of second back side pads 254_p respectively connected to the plurality of second through vias 252_p may be arranged on the second upper protection layer 256_p. According to embodiments, the plurality of second back side pads 254_p may include a plurality of second back side power pads 254a_p respectively connected to the plurality of second power through vias 252a_p, a plurality of second back side dummy pads 254b_p respectively connected to the plurality of second dummy through vias 252b_p, and a plurality of second back side signal pads 254c_p respectively connected to the plurality of second signal through vias 252c_p.

According to embodiments, in a plan view, at least one of the plurality of second back side dummy pads 254b_p may be arranged between each of the plurality of second back side signal pads 254c_p. According to embodiments, in a plan view, at least one of the plurality of second back side dummy pads 254b_p may be arranged between two second back side signal pads 254c_p of the plurality of second back side signal pads 254c_p. According to embodiments, in a plan view, the plurality of second back side dummy pads 254b_p may be arranged to surround any one of the plurality of second back side signal pads 254c_p.

According to embodiments, each of the plurality of first back side power pads 254a_q of the first semiconductor chip 200_q may be connected to a second front side power pad 244a_p of the second semiconductor chip 200_p via the second power connection terminal 248a_p. According to embodiments, each of the plurality of first back side dummy pads 254b_q of the first semiconductor chip 200_q may be connected to a second front side dummy pad 244b_p of the second semiconductor chip 200_p via the second dummy connection terminal 248b_p. According to embodiments, each of the plurality of first back side signal pads 254c_q of the first semiconductor chip 200_q may be connected to a second front side signal pad 244c_p of the second semiconductor chip 200_p via the second signal connection terminal 248c_p.

In the semiconductor package 1000 according to embodiments, the first back side dummy pad 254b_q of the first semiconductor chip 200_q and the second front side dummy pad 244b_p of the second semiconductor chip 200_p may be connected to the first dummy connection terminal 248b_q, a heat dissipation path may be formed not only in a single semiconductor chip unit but between the first semiconductor chip 200_q and the second semiconductor chip 200_p, which are stacked, and accordingly, the heat dissipation characteristics in the vertical direction (Z direction) of the entirety of the semiconductor package 1000 may be improved.

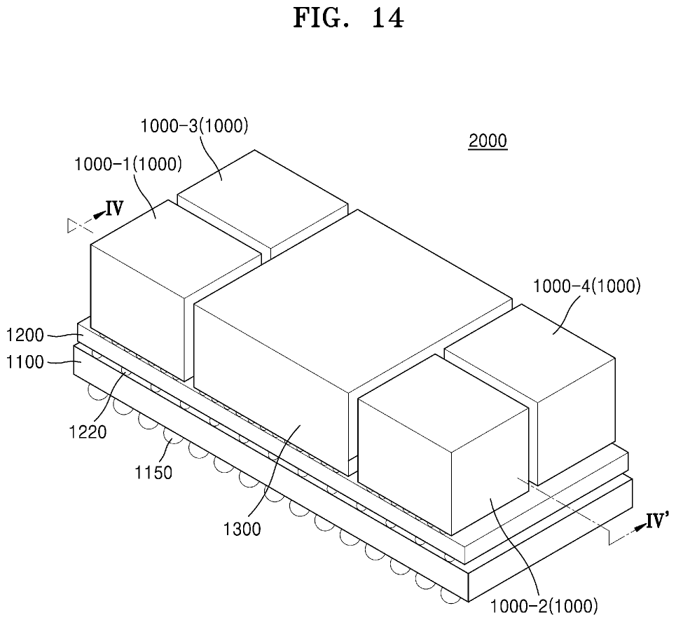

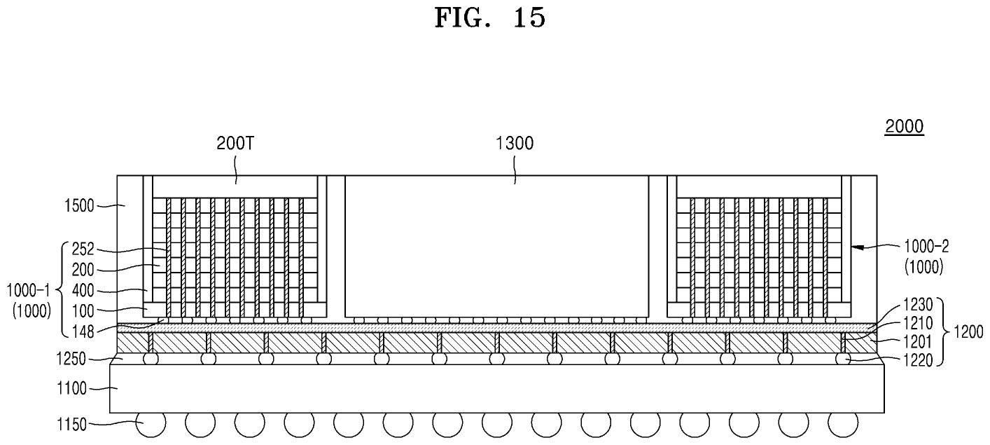

FIGS. 14 and 15 are respectively a perspective view and a cross-sectional view of a system package 2000 including the semiconductor package 1000, according to embodiments.

FIG. 15 is a cross-sectional view of region taken along line IV-IV′ in FIG. 14, and in FIG. 14, an external sealing material is omitted and not illustrated. Descriptions given with reference to FIG. 12 together, and duplicate descriptions already given with reference to FIGS. 1 through 11 are briefly provided or omitted.

Referring to FIGS. 14 and 15, the system package 2000 (hereinafter, simply referred to as a ‘system package’) of the present embodiment may include the semiconductor package 1000, a package substrate 1100, a silicon (Si) interposer 1200, a central semiconductor chip 1300, and an external sealing material 1500.

The semiconductor package 1000 may include first through fourth semiconductor packages 1000-1 through 1000-4, as illustrated in FIG. 14. The first through fourth semiconductor packages 1000-1 through 1000-4 may be arranged by two on both sides of the central semiconductor chip 1300 on the Si interposer 1200. However, in the system package 2000 of the present embodiment, the number of the semiconductor packages 1000 is not limited to four. For example, one to three or five or more semiconductor packages 1000 may be arranged on the Si interposer 1200.

The semiconductor package 1000 may include, for example, the semiconductor package 1000 of FIG. 12. Accordingly, the semiconductor package 1000 may include, for example, an HBM package. The semiconductor package 1000 may include the buffer chip 100 and a plurality of core chips 200 on the buffer chip 100, and the buffer chip 100 and the core chip 200 may include the through vias 152 and 252 therein. Descriptions of the buffer chip 100 and the core chip 200 may be the same as the descriptions of the semiconductor package 1000 with reference to FIGS. 11 and 12.

Although not illustrated in FIG. 15, the external connection terminals 148 and 248 and the adhesive layer 300 may be arranged between the buffer chip 100 and the core chip 200, and between adjacent core chips 200. In addition, as illustrated in FIG. 15, an uppermost core chip 200T of the core chips 200 may not include the through via 252.

The semiconductor package 1000 may be stacked on the Si interposer 1200 via the external connection terminal 148 under a lower surface of the buffer chip 100. The core chip 200 on the buffer chip 100 may be sealed by the sealing material 400. However, as illustrated in FIG. 15, an upper surface of the uppermost core chip 200T of the core chips 200 may not be covered by the sealing material 400. However, in some other embodiments, the upper surface of the uppermost core chip 200T may also be covered by the sealing material 400.

The package substrate 1100 may include a support substrate, on which the Si interposer 1200, the semiconductor package 1000, and the central semiconductor chip 1300 are mounted, and may include at least one layer of wiring therein. When the wirings are formed in a plurality of layers, wirings of the other layers may be connected to each other via a vertical contact. The package substrate 1100 may include, for example, a ceramic substrate, a printed circuit board (PCB), an organic substrate, an interposer substrate, etc. An external connection terminal 1150, such as a bump and a solder ball, may be arranged under a lower surface of the package substrate 1100. The external connection terminal 1150 may mount the system package 2000 on an external system substrate or an external main board.

The Si interposer 1200 may include a substrate 1201, a through via 1210, a connection terminal 1220, and a wiring layer 1230. The central semiconductor chip 1300 and the semiconductor package 1000 may be stacked on the package substrate 1100 by using the Si interposer 1200 as a medium. The Si interposer 1200 may electrically connect the central semiconductor chip 1300 and the semiconductor package 1000 to the package substrate 1100.

The substrate 1201 of the Si interposer 1200 may include, for example, a Si substrate. The through via 1210 may penetrate the substrate 1201 and extend. Because the substrate 1201 includes a Si substrate as a base, and the through via 1210 may correspond to a through silicon via (TSV). The through via 1210 may extend to the wiring layer 1230, and may be electrically connected to wirings of the wiring layer 1230. According to an embodiment, the Si interposer 1200 may include only wirings therein, and may not include a through via. The wiring layer 1230 may be arranged on an upper surface or a lower surface of the substrate 1201. For example, a position relationship between the wiring layer 1230 and the through via 1210 may be relative. An upper pad of the Si interposer 1200 may be connected to the through via 1210 via the wiring layer 1230.

The connection terminal 1220 may be arranged on a lower surface of the Si interposer 1200, and electrically connected to the through via 1210. The Si interposer 1200 may be stacked on the package substrate 1100 via the connection terminal 1220 and an underfill 1250. The connection terminal 1220 may be connected to the upper pad of the Si interposer 1200 via the through via 1210 and wirings of the wiring layer 1230. For reference, the upper pads, used for the power or ground, of the upper pads of the Si interposer 1200, may be integrated and connected together to the connection terminal 1220. Accordingly, the number of connection terminals 1220 may be less than the number of upper pads of the Si interposer 1200.

In the system package 2000 of the present embodiment, the Si interposer 1200 may be used for the purpose of converting or transmitting an electrical signal between the central semiconductor chip 1300 and the semiconductor package 1000. Accordingly, the Si interposer 1200 may not include devices, such as an active device and a passive device. Meanwhile, the underfill 1250 may be filled between the Si interposer 1200 and the package substrate 1100, and between the connection terminals 1220. In other embodiments, the underfill 1250 may also be replaced with an adhesive layer such as an adhesive film. In addition, when a molded underfill (MUF) process is performed on the package substrate 1100, the underfill 1250 may also be omitted.

The central semiconductor chip 1300 may be arranged at the central portion of the Si interposer 1200. The central semiconductor chip 1300 may include a logic chip. Accordingly, the central semiconductor chip 1300 may include a plurality of logic devices therein. The logic devices are, for example, AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OAI(OR/AND/INVERTER), AO(AND/OR), AOI(AND/OR/INVERTER), D flip-flop, reset flip-flop, master-slave flip-flop, a latch, a counter, or buffer devices. Logic devices may perform various signal processing, such as analog signal processing, analog-to-digital (A/D) conversion, and control. The central semiconductor chip 1300 may also be referred to as a graphics processing unit (GPU), a central processing unit (CPU) chip, a system on glass (SOG) chip, a micro-processor unit (MPU) chip, a graphics processing unit (GPU) chip, an application processor (AP) chip, or a control chip.

The external sealing material 1500 may cover and seal the central semiconductor chip 1300 and the semiconductor package 1000 on the Si interposer 1200. As illustrated in FIG. 15, the external sealing material 1500 may not cover the upper surfaces of the central semiconductor chip 1300 and the semiconductor package 1000. However, in other embodiments, the external sealing material 1500 may also cover the upper surface of at least one of the central semiconductor chip 1300 and the semiconductor package 1000. On the other hand, although not illustrated, the system package 2000 of the present embodiment may also further include a second external sealing material covering the Si interposer 1200 and the external sealing material 1500 on the package substrate 1100.

For reference, the structure of the system package 2000 of the present embodiment may be referred to as a 2.5 dimensional (2.5D) package structure, and the 2.5D package structure may have a relative concept of a 3 dimensional (3D) package structure, in which all semiconductor chips are stacked together and there is not a Si interposer. The 2.5D package structure and the 3D package structure may all be included in a system in package (SIP) structure.

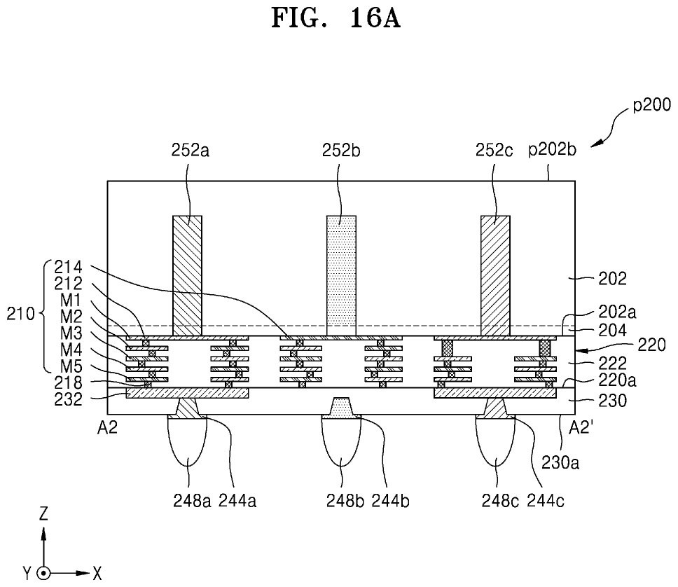

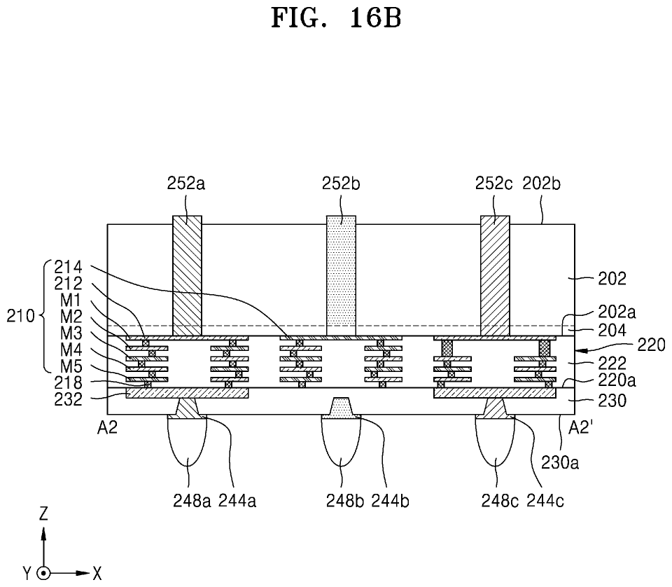

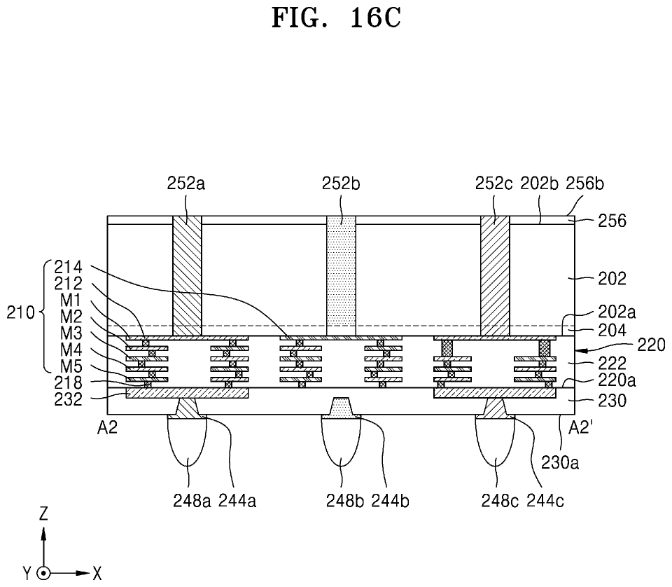

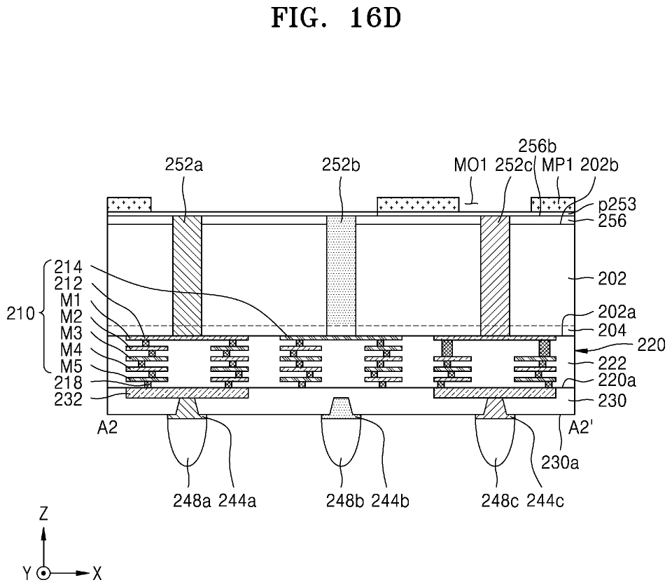

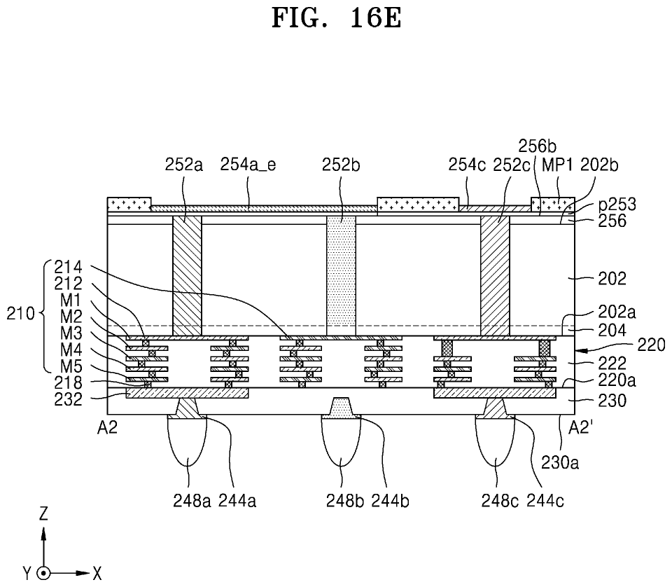

FIGS. 16A through 16E illustrate cross-sectional views illustrating a method of manufacturing the semiconductor chip 200c according to a process sequence, according to embodiments, and are cross-sectional views of the portion corresponding to the cross-sectional view taken along line A2-A2′ in FIG. 8. Descriptions already given with reference to FIGS. 1 through 15 are briefly described or omitted. For example, as described with reference to FIGS. 2, 8, and 10, it may be clearly understood that the numbers of through vias, back side pads, and front side pads may be formed in plural, and the planar arrangement relationship between respective components may be understood.

Referring to FIG. 16A, a preliminary semiconductor chip p200 including the semiconductor substrate 202 may be prepared. According to embodiments, the semiconductor substrate 202 may include the active surface 202a and a preliminary inactive surface p202b opposite thereto.

According to embodiments, the multi wiring layer 220 may be arranged on the active surface 202a of the semiconductor substrate 202, and the multi wiring layer 220 may include the wiring structure 210 including the conductive wiring 212 and the dummy wiring 214. According to embodiments, the multi wiring layer 220 may include the first through fifth wiring layers M1 through M5 and the wiring via 218, and each wiring layer may include the conductive wiring 212 and the dummy wiring 214.

According to embodiments, the lower protection layer 230 may be arranged on the front surface 220a of the multi wiring layer 220, and the conductive medium pad 232 may be arranged in the lower protection layer 230 and connected to the wiring structure 210. According to embodiments, the plurality of front side pads 244 may be arranged on the front surface 230a of the lower protection layer 230. According to embodiments, the plurality of front side pads 244 may include the plurality of front side power pads 244a, the plurality of front side dummy pads 244b, and the plurality of front side signal pads 244c. According to embodiments, each of the plurality of front side power pads 244a and the plurality of front side signal pads 244c may be connected to the conductive medium pad 232. According to embodiments, a power connection terminal 248a may be attached to a front surface of each of the plurality of front side power pads 244a, a dummy connection terminal 248b may be attached to a front surface of each of the plurality of front side dummy pads 244b, and a signal connection terminal 248c may be attached to a front surface of each of the plurality of front side signal pads 244c.

According to embodiments, the plurality of through vias 252 extending in the vertical direction (Z direction) and contacting the wiring structure 210 may be embedded in the semiconductor substrate 202. According to embodiments, the plurality of through vias 252 may not extend to the preliminary inactive surface p202b of the semiconductor substrate 202. For example, an upper portion of the plurality of through vias 252 including an upper surface of the plurality of through vias 252 may be embedded in the semiconductor substrate 202, and may not to be exposed to the outside. According to embodiments, the plurality of through vias 252 may include the plurality of power through vias 252a, the plurality of dummy through vias 252b, and the plurality of signal through vias 252c. According to embodiments, the plurality of power through vias 252a and the plurality of signal through vias 252c may be connected to the conductive wiring 212, and the plurality of dummy through vias 252b may be connected to the dummy wiring 214.

Referring to FIGS. 16A and 16B together, a portion of the semiconductor substrate 202 may be removed from the preliminary inactive surface p202b of the semiconductor substrate 202, and may form the inactive surface 202b opposite to the active surface 202a. Accordingly, portions of the upper side of the plurality of through vias 252 may protrude onto the inactive surface 202b of the semiconductor substrate 202. For example, a portion of the plurality of through vias 252 may be embedded in the semiconductor substrate 202, and the other portion thereof may protrude from the inactive surface 202b of the semiconductor substrate 202 to the outside of the semiconductor substrate 202.

Referring to FIGS. 16B and 16C together, the upper protection layer 256 may be formed on the inactive surface 202b of the semiconductor substrate 202. According to embodiments, the upper protection layer 256 may be formed by performing a chemical mechanical polishing (CMP) process to expose the upper surface of the plurality of through vias 252, after forming a preliminary upper protection layer (not illustrated) covering the upper surface of the plurality of through vias 252 on the inactive surface 202b of the semiconductor substrate 202. According to embodiments, the upper protection layer 256 may be formed to surround a portion of the upper side of the plurality of through vias 252 protruding from the inactive surface 202b of the semiconductor substrate 202.

Referring to FIGS. 16C and 16D together, a preliminary pad seed layer p253 may be formed on the rear surface 256b of the upper protection layer 256. For example, the preliminary pad seed layer p253 may be formed by using an atomic layer lamination (ALD) process, a chemical vapor deposition (CVD) process, a physical vapor deposition (PVD) process, a plasma-enhanced CVD (PECVD) process, a low-pressure CVD (LPCVD) process, etc. According to embodiments, the upper surfaces of the plurality of through vias 252 may be covered by the preliminary pad seed layer p253. Thereafter, a mask pattern MP1 including a mask opening MO1 may be formed on the preliminary pad seed layer p253. According to embodiments, the mask pattern MP1 may include a photoresist, a spin-on hard mask (SOH), an amorphous carbon layer (ACL), etc.

Referring to FIGS. 16D and 16E together, from the resultant product of FIG. 16D, the plurality of back side pads 254 partially filling the mask opening MO1 may be formed by using a plating process. According to embodiments, the plurality of back side pads 254 may include the plurality of back side expansion pads 254a_e, the plurality of back side dummy pads 254b (refer to FIG. 4), and the plurality of back side signal pads 254c. The planar arrangement relationship of the plurality of back side pads 254 may be understood in the same manner as described with reference to FIG. 8.

According to embodiments, the plurality of back side expansion pads 254a_e, the plurality of back side dummy pads 254b, and the plurality of back side signal pads 254c may be formed together by using one process. According to embodiments, the plurality of back side pads 254 may have a structure in which different metal materials are sequentially stacked. For example, the plurality of back side expansion pads 254a_e and the plurality of back side signal pads 254c may be formed by sequentially stacking Ti, Cu, Ni, and Au.

Referring to FIGS. 16E and 9, after removing the mask pattern MP1 from the resultant product of FIG. 16E, a portion of the preliminary pad seed layer p253 may be removed by using an etching process, and then, the pad seed layer 253 may be formed. In this case, a portion of the rear surface 256b of the upper protection layer 256, that does not overlap the plurality of back side pads 254, may be exposed.

While aspects of the inventive concept have been particularly shown and described with reference to embodiments thereof, it will be understood that various changes in form and details may be made therein without departing from the spirit and scope of the following claims.

What is claimed is:

1. A semiconductor chip comprising:
a semiconductor substrate including an active surface and an inactive surface facing the active surface;
a multi wiring layer arranged on the active surface of the semiconductor substrate, and including a wiring structure having at least two layers and including a conductive wiring and a dummy wiring;
a lower protection layer arranged on a front surface of the multi wiring layer, and including a conductive medium pad connected to the conductive wiring;
an upper protection layer on the inactive surface of the semiconductor substrate;
a plurality of through vias configured to penetrate the semiconductor substrate and the upper protection layer, and including a plurality of power through vias, a plurality of signal through vias, and a plurality of dummy through vias; and
a plurality of back side pads arranged on a rear surface of the upper protection layer, and connected to the plurality of through vias,
wherein the plurality of dummy through vias are connected to the wiring structure.

2. The semiconductor chip of claim 1, wherein the plurality of dummy through vias are connected to the dummy wiring, and
the dummy wiring is connected to the conductive wiring.

3. The semiconductor chip of claim 1, further comprising a plurality of front side pads including a plurality of front side power pads, a plurality of front side signal pads, and a plurality of front side dummy pads, and arranged on a front surface of the lower protection layer,
wherein each of the plurality of front side power pads and the plurality of front side signal pads is connected to the conductive medium pad.

4. The semiconductor chip of claim 3, further comprising a dummy medium pad arranged in the lower protection layer, and connected to the dummy wiring,
wherein the plurality of front side dummy pads are connected to the dummy medium pad.

5. The semiconductor chip of claim 1, wherein at least one of the plurality of dummy through vias is, in a plan view, arranged between two signal through vias selected from among the plurality of signal through vias.

6. The semiconductor chip of claim 1, wherein the plurality of dummy through vias are, in a plan view, arranged to surround at least one of the plurality of signal through vias.

7. The semiconductor chip of claim 1, wherein the plurality of back side pads comprise:
a plurality of back side power pads respectively connected to the plurality of power through vias;
a plurality of back side signal pads respectively connected to the plurality of signal through vias; and
a plurality of back side dummy pads respectively connected to the plurality of dummy through vias,
wherein the plurality of back side dummy pads comprise a dot pad connected to one of the plurality of dummy through vias, and a line pad connected to two or more of the plurality of dummy through vias.

8. The semiconductor chip of claim 7, wherein the line pad is, in a plan view, is arranged to surround at least one of the plurality of back side signal pads.

9. The semiconductor chip of claim 1, wherein the plurality of back side pads comprise:
a plurality of back side power pads respectively connected to the plurality of power through vias;
a plurality of back side signal pads respectively connected to the plurality of signal through vias; and
a plurality of back side dummy pads respectively connected to the plurality of dummy through vias,
wherein at least one of the plurality of back side power pads is connected to at least one of the plurality of back side dummy pads.

10. The semiconductor chip of claim 1, wherein the plurality of back side pads comprise a back side expansion pad connected together to at least one of the plurality of power through vias and the plurality of dummy through vias.

11. A semiconductor chip comprising:
a semiconductor substrate including an active surface and an inactive surface facing the active surface;
a multi wiring layer arranged on the active surface of the semiconductor substrate, and including at least two layers of each of a conductive wiring and a dummy wiring;
a lower protection layer including, therein, a conductive medium pad connected to the conductive wiring, and a dummy medium pad connected to the dummy wiring, the lower protection layer being arranged on a front surface of the multi wiring layer;
an upper protection layer on the inactive surface of the semiconductor substrate;
a plurality of through vias including a plurality of power through vias, a plurality of signal through vias, and a plurality of dummy through vias, and configured to penetrate the semiconductor substrate and the upper protection layer; and
a plurality of back side pads including a plurality of back side power pads respectively connected to the plurality of power through vias, a plurality of back side signal pads respectively connected to the plurality of signal through vias, and a plurality of back side dummy pads respectively connected to the plurality of dummy through vias, the plurality of back side pads being arranged on a rear surface of the upper protection layer,
wherein at least one of the plurality of back side power pads is connected to at least one of the plurality of back side dummy pads.

12. The semiconductor chip of claim 11, wherein the plurality of power through vias and the plurality of signal through vias are connected to the conductive wiring, and the plurality of dummy through vias are connected to the dummy wiring.

13. The semiconductor chip of claim 11, further comprising a plurality of front side pads including a plurality of front side power pads, a plurality of front side signal pads, and a plurality of front side dummy pads, the plurality of front side pads being arranged on a front surface of the lower protection layer,
wherein each of the plurality of front side power pads and the plurality of front side signal pads is connected to the conductive medium pad, and
wherein the plurality of front side dummy pads are connected to the dummy medium pad.

14. The semiconductor chip of claim 11, wherein at least one of the plurality of dummy through vias is, in a plan view, arranged between two signal through vias selected from among the plurality of signal through vias.

15. The semiconductor chip of claim 11, wherein the plurality of back side dummy pads comprise a dot pad connected to one of the plurality of dummy through vias, and a line pad connected to two or more of the plurality of dummy through vias, and
wherein the line pad is, in a plan view, arranged to surround at least one of the plurality of back side signal pads.

16. The semiconductor chip of claim 11, wherein the dummy wiring is connected to the conductive wiring.

17. A semiconductor package comprising:
a first semiconductor chip; and
a second semiconductor chip on the first semiconductor chip,
wherein the first semiconductor chip comprises:
a first semiconductor substrate including a first active surface and a first inactive surface, which are opposite to each other;
a first dummy wiring arranged in a first multi wiring layer on the first active surface of the first semiconductor substrate;
a plurality of first back side dummy pads arranged on the first inactive surface of the first semiconductor substrate; and
a plurality of first dummy through vias configured to penetrate the first semiconductor substrate and connected to the first dummy wiring and the plurality of first back side dummy pads,
wherein the second semiconductor chip comprises:
a second semiconductor substrate including a second active surface and a second inactive surface, which are opposite to each other;
a second dummy wiring arranged in a second multi wiring layer on the second active surface of the second semiconductor substrate; and
a plurality of second front side dummy pads connected to the second dummy wiring, and arranged on a front surface of the second multi wiring layer, and
wherein the plurality of first back side dummy pads are respectively connected to the plurality of second front side dummy pads.

18. The semiconductor package of claim 17, wherein the plurality of first back side dummy pads comprise a dot pad connected to one of the plurality of first dummy through vias, and a line pad connected to two or more of the plurality of first dummy through vias.

19. The semiconductor package of claim 18, wherein the first semiconductor chip further comprises:
a plurality of first signal through vias configured to penetrate the first semiconductor substrate; and
a plurality of first back side signal pads arranged on the first inactive surface of the first semiconductor substrate, and connected to the plurality of first signal through vias, and
wherein the line pad is, in a plan view, arranged to surround at least one of the plurality of first back side signal pads.

20. The semiconductor package of claim 17, wherein the first semiconductor chip further comprises a first conductive wiring arranged in the first multi wiring layer, and
wherein the first dummy wiring is connected to the first conductive wiring in the first multi wiring layer.
